(19) United States
(12) Patent Application Publication
(10) Pub. No.: US 2010/0170086 A1
(43) Pub. Date: Jul. 8, 2010

(54) DEVICE, UNIT, SYSTEM AND METHOD FOR THE MAGNETICALLY-ASSISTED ASSEMBLING OF CHIP-SCALE, AND NANO AND MICRO-SCALE COMPONENTS ONTO A SUBSTRATE

(75) Inventors: Qasem Ramadan, Singapore (SG); Seung Uk Yoon, Singapore (SG); Vaidyanathan Kripesh, Singapore (SG); Poi Siong Teo, Singapore (SG); Mahadevan Krishna Iyer, Singapore (SG)

Correspondence Address: CONNOLLY BOVE LODGE & HUTZ LLP, 1875 EYE STREET, N.W., SUITE 1100, WASHINGTON, DC, 20006, US

(73) Assignee: AGENCY FOR SCIENCE, TECHNOLOGY AND RESEARCH, Connexis (SG)

(21) Appl. No.: 12/513,492

(22) PCT Filed: Nov. 3, 2006
(86) PCT No.: PCT/SG06/00330

§ 371 Date: Mar. 15, 2010

(51) Int. Cl. H05K 3/30; B23P 19/00

(52) U.S. Cl. 29/834; 29/740

(57) ABSTRACT

A magnetically-assisted chip assembly unit for assembling at least one chip having a mounting surface and an attachment surface, wherein the attachment surface supports a magnetisable layer thereon and opposes said mounting surface, onto a substrate that has a corresponding chip mounting surface. The unit comprises a template wafer having at least one recess adapted to accommodate therein said chip; and a master wafer having at least one magnetisable element; wherein the template wafer is mounted on the master wafer and said magnetisable element is located at least proximate to the at least one recess such that the magnetisable element is capable of manipulating the chip into the recess, via its magnetisable layer when the magnetisable element is magnetized and generates a magnetic field. Once in the recess, the attachment surface of the chip faces at least a portion of the recess and the mounting surface of the chip faces an opening of the recess.

The present invention relates to the field of assembly devices for use in assembling chips and micro-components onto substrates, and in particular, to a device, unit, system and method for the magnetically-assisted assembling of chip-scale, nano-nano-scale and micro-scale components onto a substrate.

Assembling heterogeneous devices that are made of different materials such as Gallium (Ga) or Arsenic (As), for example, onto a substrate of a different material such as Si, for example, is presently carried out in the production of integrated circuits (ICs) and in the manufacture of optical low—cost and high—performance electronics, optoelectronics, and micro—electro-mechanical systems (MEMS). Although these technologies have wide ranging applications, the manufacturing processes involved in each of the above-mentioned technologies are very similar. As such, difficulties encountered in the assembly process of ICs, for example, are generally also encountered in the fabrication processes of the other technologies with similar production techniques, such as in the fabrication of MEMS.

Using the production of ICs as an illustrative example, products having ICs typically include at least one semi-conductor chip mounted on a substrate. The semi-conductor chip is usually packaged by solder bumping, in the case of flip chips, or has bond pads on its respective mounting surfaces prior to being mounted on the substrate. During the manufacturing of the product, these packaged chips are assembled onto their respective substrates. These substrates include mounting positions, which usually are bond pads that correspond either directly or indirectly to the bond pads or solder bumps on the mounting surfaces of the packaged chip. The packaged chips connect to the substrate, electrically and physically, via said bond pads after undergoing a process of either solder reflow or wire bonding, for example.

As an ever increasing number of transistors are included onto each semi-conductor chip, the requirement for a greater level of electrical connectivity between the packaged chip and its respective substrate has increased. In order to meet this increased demand in connectivity, in the case of flip chips having solder bumps for example, the number of solder bumps present has increased while the overall size of the packaged chip has actually decreased. In order to cope with this paradox of having more solder bumps on a smaller surface, the size of each solder bump as well as the pitch (distance between two adjacent solder bumps) have been reduced significantly. This reduction in size of the electrical connectors (solder bumps and bond pads), and of the chip as a whole, raises a difficulty in the aforesaid assembly process. In this respect, during the assembly process, the packaged chip and its connectors have to be precisely aligned with the bond pads of its corresponding substrate, a task made increasingly difficult due to the decreasing electrical connector sizes.

In order to overcome this difficulty, one approach involves mating the packaged semi-conductor chip with its substrate via the use of a robotics arm. This approach is disclosed in U.S. Pat. No. 5,034,802. In this patent, the assembly process uses a robotic arm to physically pick, align and attach packaged chips onto a substrate. This approach has the limitation that the assembly of chips takes place sequentially, i.e. one by one, and therefore, reduces efficiency, especially when each substrate typically accommodates a plurality of packaged chips. Furthermore, with chip sizes shrinking, the picking up and placement of such small scale chips may prove to be increasingly difficult.

Another method adopted is disclosed in U.S. Pat. No. 5,545,291 where the assembly of microstructures onto a substrate is achieved via fluid transport. The microstructures, which are shaped as blocks, self-align themselves into recessed regions. The recessed regions themselves correspond to the shape of the microstructures, such that the microstructure becomes integral with the substrate. In this method, the microstructure is first transferred into a fluid to create a slurry, which in turn is then poured over the substrate. The microstructures within the slurry flow over the substrate and engage into the recesses on the substrate thereby completing the alignment process.

A further approach is described in the article “The Magnetic Field-Assisted Assembly of Nanoscale Semiconductor Devices: A New Technique” by Shet et al. JOM, October 2004; 56; 10, involves the use of a magnetic field to assist in the assembly of semi-conductor devices. This publication discloses that prior to the assembly process, recesses are patterned directly onto the substrate and that the shape and thickness of the nano units to be assembled onto said substrate match the shape and depth of the recesses on the substrate. A ferromagnetic material is deposited on the bottom of the recesses of the substrate while a soft magnetic layer is formed on the nano units. During the assembly process, a magnetic field is applied directly to the substrate and the nano units are scattered thereon. The magnetised recesses of the substrate attract the nano units having a soft magnetic layer thereon such that the nano units become magnetised and attached to the recesses of the substrate. In this approach both the nano units and the substrate must be patterned beforehand thereby leading to long processing times. In addition, having ferromagnetic or hard magnetic materials on the substrate to attract the nano units causes a magnetic field to be permanently present on the devices, which in turn, may affect the functionality of the assembled device, especially if the assembled devices are intended for use in microelectronic applications, for example.

Despite the above-mentioned methods, there still remains a need for an effective means to carry out the assembly of chips and micro-components onto their respective substrates in an efficient, reliable and cost effective manner. In this respect, a magnetically-assisted chip and micro-component assembly unit, as defined in the appended claims, overcomes the aforesaid difficulties.

The assembly unit for the magnetically-assisted assembly of at least one chip and/or micro-component functions in conjunction with chips (and/or micro-components) having a mounting surface and an attachment surface. The attachment surface of the chip (and/or micro-component) supports a magnetisable layer thereon and opposes said mounting surface of the chip. The chip having a mounting surface and attachment surface as described is typically mounted onto a substrate that has a corresponding chip mounting surface.

It should be noted that hereon forward, the term “chip” may be taken to mean a semi-conductor chip, an optical/physical micro-component, a MEMs chip or any other micro-component or nano-component, which may be made of Si (or other materials) for example, and may not necessarily be used for the same purpose or in the same context as a semi-conductor device. Accordingly, the term “chip” used herein also includes micro-components as described in U.S. Pat. No. 5,545,291. Examples of such micro-components include, but are not limited to, gallium arsenide based microstructures such as light emitting diodes (LEDs), lasers, tunnelling transistors, Gunn oscillators, integrated circuits and solar collectors. The term “chip” also includes nano-scale components. Examples of nano-scale components, as described in the article “The Magnetic Field-Assisted Assembly of Nanoscale Semiconductor Devices: A New Technique” by Shet et al. include nano electromechanical systems (NEMS), sensors and actuators. Another example of a device that is included in the definition of the term “chip” are glass substrates that are coated with oligonucleotides and are used as “biochips” in the detection and analysis of nucleic acids in hybridization assays.

In line with the above definition of the term “chip” the assembly method described here is not limited to chip-scale level assemblies but may be used in the assembly of any of the components described above. For example, it may be the case that at least one nano and/or micro-scale component is assembled onto a substrate (which may be a semi-conductor chip, silicon wafer, MEMS substrate or any other suitable surface) using a device (of a suitable scale) and method described herein. The substrate having the nano and/or micro-scale components assembled thereon may then in turn be assembled onto another suitable substrate, such as a silicon wafer, using the same method and a suitably scaled device.

In the embodiment where the assembly of chip-scale level devices is concerned, said assembly unit includes a template wafer having at least one recess adapted to accommodate therein said chip. The assembly unit also includes a master wafer having at least one magnetisable or magnetic element. The template wafer is mounted on the master wafer such that the magnetisable or magnetic element is located at least proximate to the at least one recess such that when the magnetisable or magnetic element generates a magnetic field, the magnetic field is capable of manipulating the chip into the recess, via the magnetisable layer supported by the attachment surface of the chip. When the chip is manipulated into the recess, the attachment surface of the chip that supports the magnetisable layer faces at least a portion of the recess while the mounting surface of the chip faces the opening of the recess.

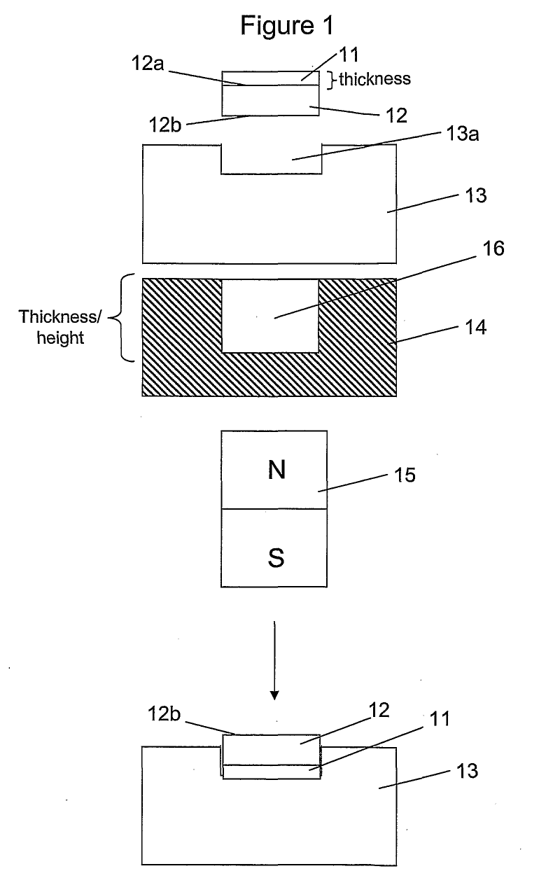

The above-mentioned magnetisable layer on the chip is the film of magnetic material deposited on chip, typically prior to dicing or assembly. This magnetisable layer, which may be permanent or non-permanent in terms of its magnetism, may be comparable to a thin film and is, in an illustrative embodiment, between about 0.1 μm—about 100 μm in thickness (see FIG. 1 where the thickness of the magnetisable layer is indicated). In contrast, the magnetisable or magnetic elements on the master wafer are typically, but not limited to, about 1 μM—about 10 mm in height. For illustrative purposes, the dimensions provided above may refer to the height of the magnetisable or magnetic elements, for example. In this context, the height may be considered to span the thickness of the master wafer (see FIG. 1 where the thickness/height of the magnetisable or magnetic elements is indicated).

In one embodiment of the invention, the master wafer may include at least one magnetic element. The magnetic element is typically made of a hard magnetic material. In this context, the term “hard magnetic material” refers to any material that exhibits spontaneous magnetization i.e. a net magnetic moment in the absence of an external magnetic field, as is in the case of permanent magnets, for example. Alternatively, “hard magnetic material” can be defined as a material having a high coercivity, where coercivity is the intensity of an applied magnetic field required to reduce the magnetization of a material to zero.

As an illustrative example, a permanent magnet having a high degree of magnetization would therefore require an applied magnetic field of high intensity (high coercivity) to reduce its magnetization to zero. Examples of “hard magnetic materials” may be, but are not limited to, nickel and cobalt with iron (alnico) and CoPtCr, which have coercivity values of about 1500—about 2000 Am⁻¹ and about 1700 Am⁻¹, respectively.

In another embodiment, the master wafer may include at least one magnetisable element. The magnetisable element is typically made of a soft magnetic material. In this context, the term “soft magnetic material” typically refers to a material that exhibits magnetic properties when subjected to an applied magnetic field, which causes its atomic dipoles to align with the applied magnetic field, as is the case with non-permanent magnets, for example. “Soft magnetic materials” can also be defined as materials having a low coercivity according to the aforesaid definition of coercivity. Examples of soft magnetic materials include, but are not limited to, iron, nickel and cobalt and alloys thereof. In this respect, the coercivity of the cobalt and nickel for example, are about 20 Am⁻¹ and about 150 Am⁻¹, respectively.

In yet another embodiment, master wafer may include only magnetisable elements, magnetic elements or a combination of at least one magnetisable element and at least one magnetic element. As such, in order to facilitate the description of the various embodiments of the invention, the term “magnetic element” is to be taken hereon forward to refer to both hard (permanent) and soft (non-permanent) magnetic materials (i.e. magnetisable elements and magnetic elements) unless stated otherwise.

In one specific exemplary embodiment, the assembly unit includes a template wafer and a master wafer, wherein the template wafer has a plurality (two or more) of recesses and the master wafer has a corresponding plurality (two or more) of magnetic elements, respectively. Each recess of the template wafer is arranged such that it corresponds to a respective chip mounting position on a substrate. In this embodiment, each of the plurality of magnetic elements is located at least proximate to at least one recess such that when the magnetic elements generate a magnetic field, the magnetic field is capable of manipulating the magnetisable chip. In order to generate said magnetic field, each of the magnetic elements must have its one end magnetically polarised as a north pole and its other end magnetically polarised as a south pole.

In all embodiments where the master wafer includes at least one magnetisable element (i.e. made of a soft magnetic material), the assembly unit typically further includes a magnetic source (or source magnet) proximate to the magnetisable element. In this respect, the magnetic source may be considered to be adapted to induce a state of magnetism in the magnetisable element, such that the magnetisable element generates a magnetic field sufficient to manipulate the chip via the magnetisable layer of the chip.

In the above embodiment having a magnetic source, the magnetic source may be a permanent magnet or an electromagnet. In either case, the magnetic source may be mounted onto a magnetic source carrier. The magnetic source carrier is adapted such that the magnetic source mounted thereon is translatable in a vertical and/or horizontal axis with respect to the master wafer. Having a translatable magnetic source, in the case of the embodiment having a magnetisable element allows for the magnetic flux density of the field applied to the magnetisable element to be varied by varying the distance of the magnetic source to the magnetisable element. This in turn allows the strength of the magnetic field generated by the magnetisable element, to be varied and adjusted as needed to manipulate the chips. In the embodiment where the magnetic source is an electromagnet, the magnetic flux density of the magnetisable element may be controlled by varying the amount of current supplied to the electromagnet, in addition to controlling the position of the magnetic source.

In the embodiment of the invention where the master wafer includes at least one magnetic (i.e. hard magnetic material) element, said magnetic element may be a permanent magnet. In this embodiment, as the magnetic (hard magnetic material) element already generates a magnetic field on its own accord, there is typically no need for an external magnetic source, unlike the above embodiment having magnetisable elements that are made from soft magnetic materials. In any case, additional magnetic sources may still be used in conjunction with the magnetic element (hard magnetic material) if the strength of the magnetic field is required to be higher.

In another embodiment of the invention, the assembly unit may further include at least one solenoid, wherein said at least one solenoid is arranged at least proximate to the periphery of the master wafer. The solenoid is arranged such that it is capable of modulating any magnetic field generated by the magnetic elements (both soft and/or hard), and therefore, is also capable of manipulating the chip having said magnetisable layer thereon.

In yet another embodiment of the invention, the template wafer may be removably mounted onto the master wafer. In this embodiment, the template wafer is removable from the master wafer after all the chips have been arranged into the recesses of the wafer template in order to facilitate the further processing of the chips. In this regard, the further processing of the chips may, in an instance where the chip is a semi-conductor chip, typically include the bonding processes that physically and electrically connect said semi-conductor chip to the substrate, for example.

In another embodiment, the master wafer and/or template wafer may be rotatable about their respective diametric axis either individually or collectively. In this embodiment, the master wafer, with the template wafer mounted thereon, may be rotatable such that they are inverted from their original positions via a 180 degree rotation about their diametric axis, for example. Again, as in the embodiment where the wafer template is removable, such a feature serves to aid in the further processing of the chips as it provides flexibility in the positioning of the template wafer (and the master wafer, if so attached thereto) with respect to the substrate.

As an exemplary embodiment, the rotation of the master wafer and template wafer having chips arranged therein, may result in the chips being immediately aligned with the substrate onto which said chips are to be mounted following said rotation. Accordingly, having said rotatable feature of the master wafer and/or template wafer may enable the processing/fabrication time to be reduced thereby increasing efficiency during a manufacturing process and efficiency in a product assembly line.

In yet another embodiment of the invention, the assembly unit may further include a vibration mechanism. The vibration mechanism is adapted such that the vibrations serve to facilitate the entry of the chip into the recess of the template wafer. In the embodiment where the magnetic elements are soft magnetic materials and are used in conjunction with the magneto source, the vibration mechanism may only vibrate the wafer template and the master wafer. In this regard, any external magnetic source (permanent magnet, electromagnet or solenoid) applied to the magnetic (soft magnetic materials) elements is typically not vibrated as that may give rise to an inconsistent magnetic field being induced in the magnetisable elements and generated by the magnetisable elements.

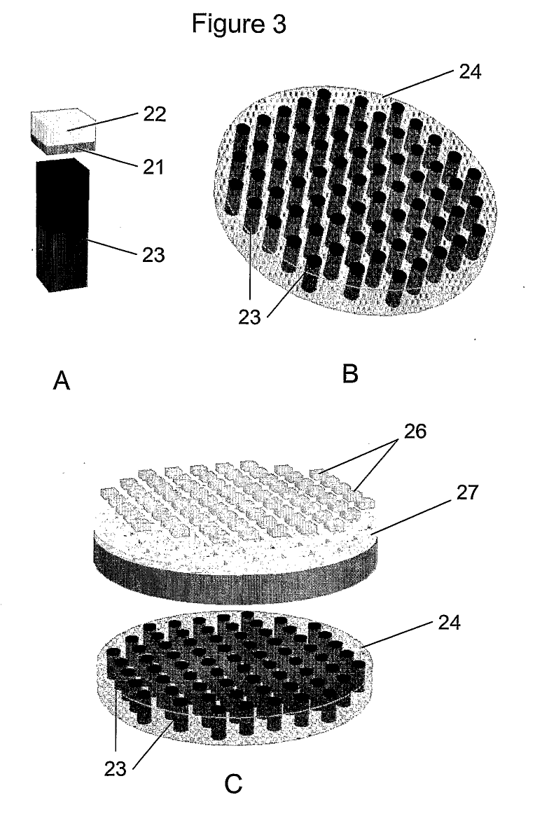

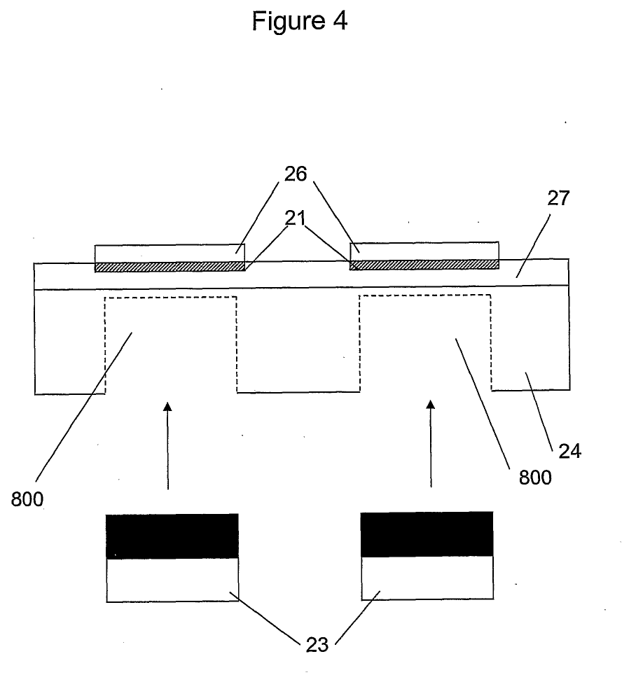

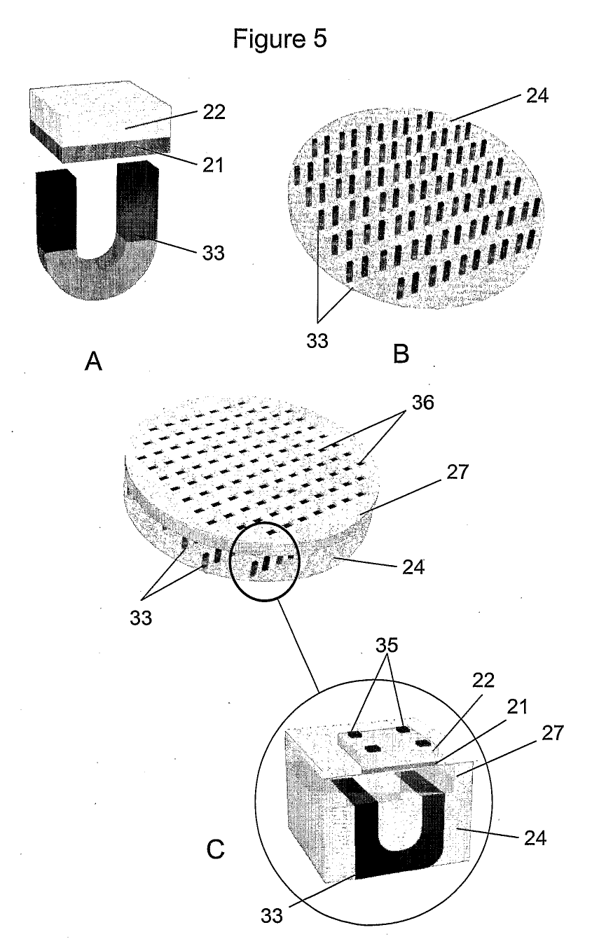

In one embodiment, the magnetic element may be embedded within the master wafer (see FIG. 3 or FIG. 5). Alternatively, the magnetic element may be inserted into the master wafer as illustrated in FIG. 4. In yet another alternative, the magnetic element may be arranged on a surface of the master wafer. In all embodiments of the assembly unit described herein, the magnetic element may be, but is not limited to, a circular rod, a rectangular bar, U-shaped (horse-shoe shaped) or of any other suitable form, for example.

The magnetic element may be made from any suitable material. Examples of such suitable materials for soft magnetic materials may be, but are not limited to, iron, cobalt, nickel, Ni₁₋ₓZnₓFeO₃ and Permalloy (Ni₈₁Fe₁₉). Examples of suitable materials for hard magnetic materials may be, but are not limited to, composites of powdered iron oxide and barium/strontium carbonate ceramic, alloys of aluminium, nickel and cobalt with iron (alnico), samarium cobalt, neodymium iron boron (NdFeB), CoPtCr or any combination thereof.

A further aspect of the present invention relates to a method of assembling at least one chip having a mounting surface and an attachment surface that opposes said mounting surface, onto a substrate that has a corresponding chip mounting surface, said method comprising:
forming a magnetisable layer adjacent on the attachment surface of the chip;
placing the chip having the magnetisable layer on a template wafer, said template wafer having at least one recess adapted to accommodate therein said chip;
generating a suitable magnetic field by means of a magnetic field generation device such that said magnetic field is capable of manipulating the chip into the recess, via its magnetisable layer, such that the attachment surface of the chip faces at least a portion of the recess and the mounting surface of the chip faces an opening of the recess; and
aligning the template wafer with respect to the substrate such that the mounting surface of the chip contained in the recess contacts the mounting surface of the substrate.

In one embodiment of the method of the present invention, a polymer-based film may be first formed on the attachment surface prior to forming the magnetisable layer, i.e. it is an intermediate layer between the attachment surface and the magnetisable layer. The polymer-based film thickness may be between about 5 μm to about 200 μm. The film may be either multilayered or of a unitary layer and may have adhesive qualities conferred either by its natural properties, by chemical treatment or by (ultraviolet) UV exposure, for example.

This polymer-based film may be preformed as a solid or prepared by the curing or hardening of liquid polymers. In the exemplary embodiment where the chip is a semi-conductor chip, and where the film is a preformed solid, said film may be laminated on the semi-conductor chip while still in its wafer form (i.e. a whole wafer of semi-conductor chips) before dicing. In the exemplary embodiment where the films are prepared from the curing or hardening of liquid polymers, the liquid polymer may be coated on the wafer by spin-coating method, for example followed by curing or hardening.

As mentioned, the polymer-based film may have adhesive qualities. In an exemplary embodiment, the polymer-based film may have double-sided adhesive qualities meaning that one side of the polymer film attaches to the attachment surface of the chip while its other side is capable of receiving and supporting the magnetisable layer or is itself a magnetisable layer. In this respect, the double-sided polymer film of the exemplary embodiment may be a double-sided tape with one side thereof being an adhesive polymer and its other side being metallic in nature, thereby providing a potentially magnetisable layer. Examples of such double-sided tapes, which are commercially available from 3M, include, but are not limited to, acrylic adhesive polymer aluminium foil, silicone adhesive polymer aluminium foil and rubber adhesive polymer aluminium foil.

In one embodiment of this aspect of the invention, the magnetisable layer may have an additional layer or film (a protective layer) on it that serves to protect the magnetisable layer from physical and/or chemical damage, for example. Alternatively, or in conjunction, the recess may also have such a protective layer on its inner surfaces in order to avoid direct contact of said inner surfaces with the magnetisable layer. In any case, when the assembly unit is in operation, the magnetic field generated is capable of manipulating the chip into the recess, such that the attachment surface of the chip faces at least a portion of the recess and the mounting surface of the chip faces an opening of the recess. This is the case regardless of whether said attachment surface abuts the portion of the recess directly or indirectly (via the protective layer).

To complete the entire assembly process described above, again using the exemplary embodiment where the chip is a semi-conductor chip, the mounted semi-conductor chip is bonded to a suitable substrate. In this regard, the utilization of a wire bonding process or a solder reflowing (in the case of a flip chip design) process to electrically and physically connect the semi-conductor chip to the substrate is necessary.

As an additional step, the removal of the polymer film and the magnetisable layer deposited thereon from the attachment surface may be necessitated especially if the chip is to be used in applications where any residual magnetism may jeopardize it proper functioning. The polymer layer may be removed by mechanical means, chemical means, heating means or any combination thereof. However, and as described in more detail later on, in some instances the magnetisable layer does not interfere in the further assembly or functioning of the chip. Accordingly, in those instances, the magnetisable layer may be left on the chip. An example of such a chip may be those used in the testing of biological materials such as in the case of MEMs.

The above-mentioned method for assembling at least one chip onto a substrate that has a corresponding chip mounting surface may be implemented in a system for carrying out the same. In this regard, such a system includes a magnetically-assisted chip assembly unit, as described in the various embodiments earlier; and a bonding mechanism connect the chip to the substrate. In the exemplary embodiment where the chip is a semi-conductor chip, the bonding mechanism is used to electrically and physically connect the semi-conductor chip to the substrate.

In the exemplary embodiment of the system where the chip is a semi-conductor chip, the bonding mechanism may include a soldering mechanism, where the semi-conductor is a flip chip design, or a wire bonding mechanism. Otherwise, generally, in a further embodiment of the system, said system may also include a magnetisable layer removal means. This magnetisable layer removal means may rely on mechanical means, chemical means, heating means or any combination thereof.

In all the aforesaid embodiments, the scale of the various aspects of the present invention relate to chip-scale assembly of components. However, it should be noted, and as mentioned earlier, that the various aspects of the invention described herein are also applicable to nano-scale and micro-scale components as well by scaling down the various aspects of the invention accordingly.

In order to aid in the further understanding of the various aspects of the present invention, exemplary embodiments of said various aspects of the present invention are further described below with reference to the following appended figures in which:

FIG. 1 shows a side view of an exemplary embodiment of the present invention;

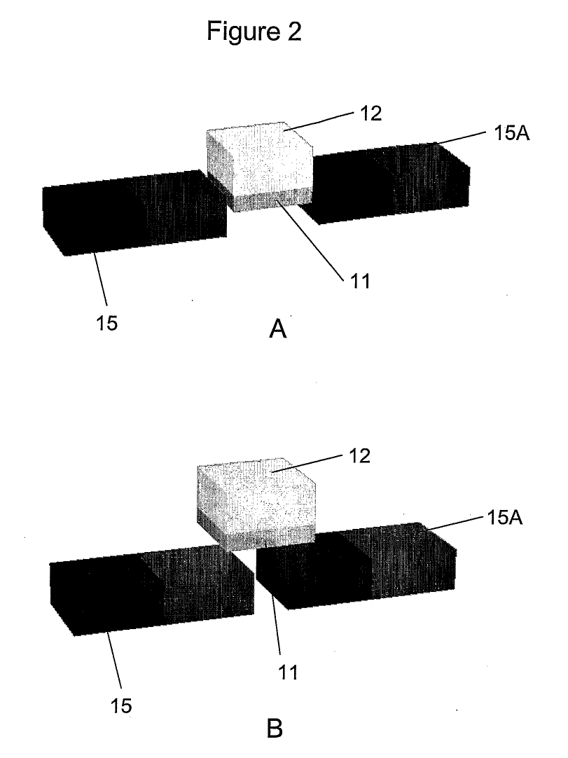

FIGS. 2A and 2B show different exemplary arrangements of a magnetic element with respect to a chip;

FIG. 3A shows a chip and an exemplary embodiment of a magnetic element;

FIG. 3B shows an exemplary embodiment of a master wafer;

FIG. 3C shows an exploded view of an exemplary embodiment of an assembly unit;

FIG. 4 shows a side view of another exemplary embodiment of an assembly unit;

FIG. 5A shows a chip and another exemplary embodiment of a magnetic element;

FIG. 5B shows another exemplary embodiment of a master wafer;

FIG. 5C shows an enlarged view of another exemplary embodiment of an assembly unit;

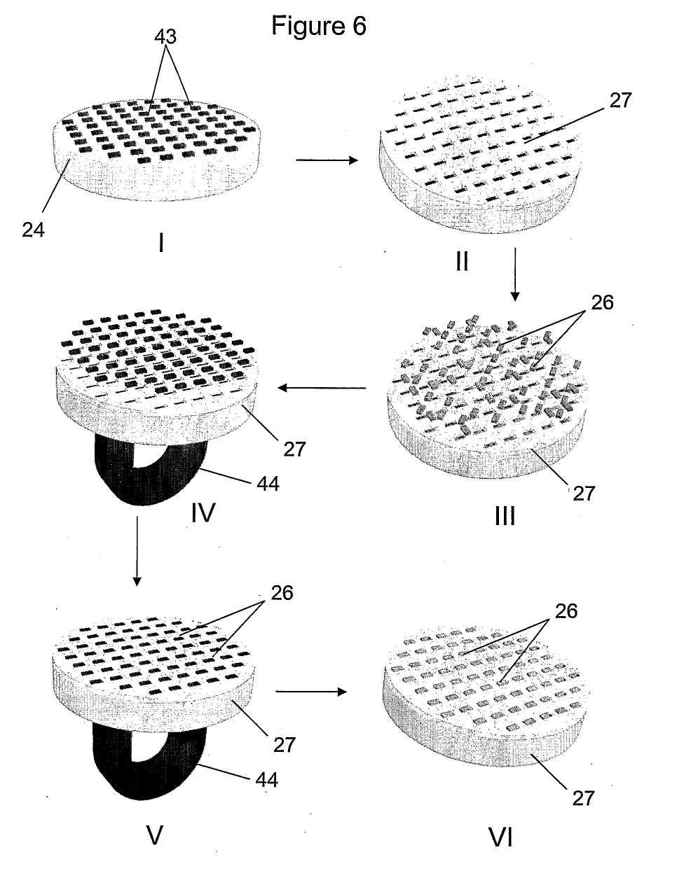

FIG. 6 shows a method of assembling chips according to an exemplary embodiment of the invention;

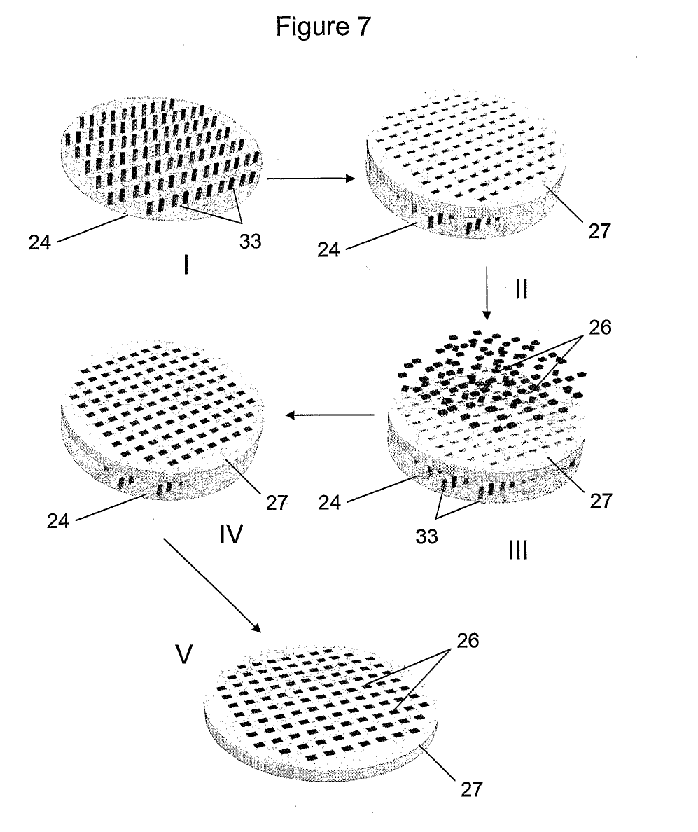

FIG. 7 shows another sequence by which chips are assembled according to an another exemplary embodiment of the invention;

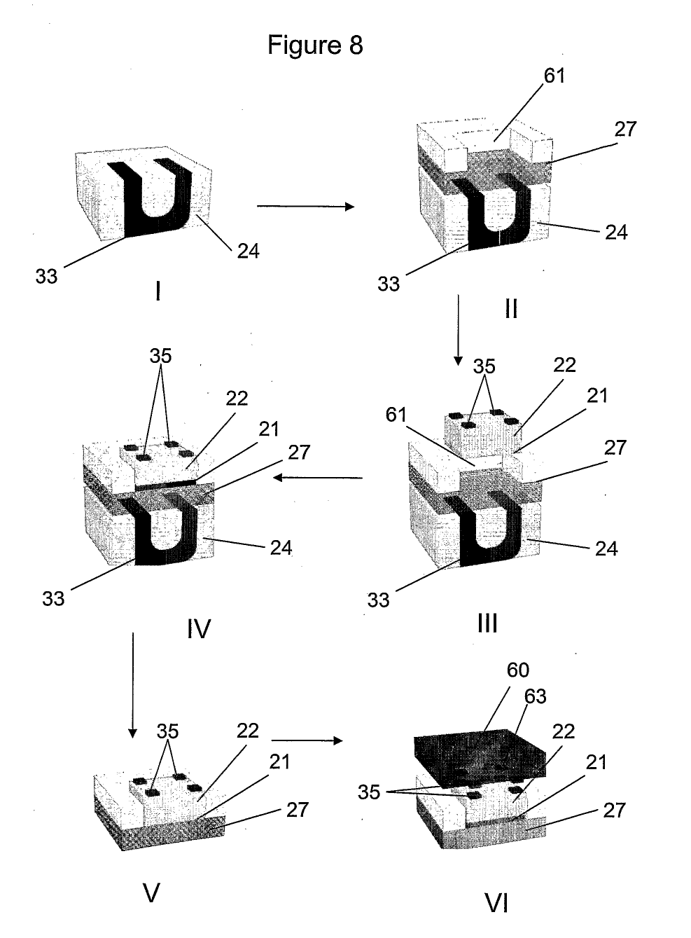

FIG. 8 shows an enlarged view of an exemplary embodiment of a method of assembling a chip onto a substrate;

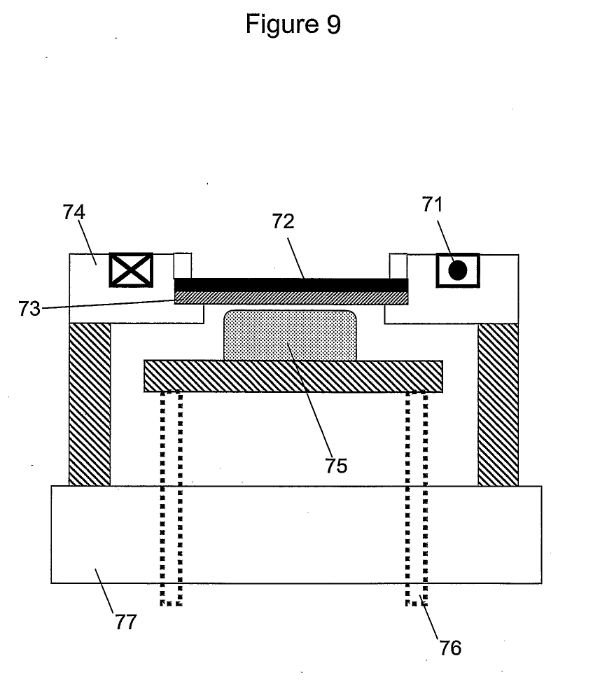

FIG. 9 shows a side view of an exemplary embodiment of the present invention;

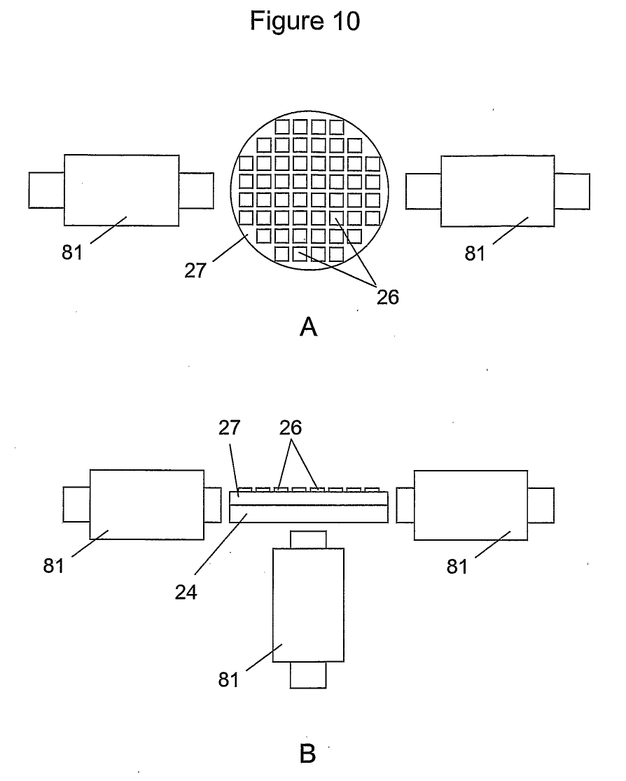

FIG. 10A and FIG. 10B show a top view and a side view of another exemplary embodiment of the present invention, respectively;

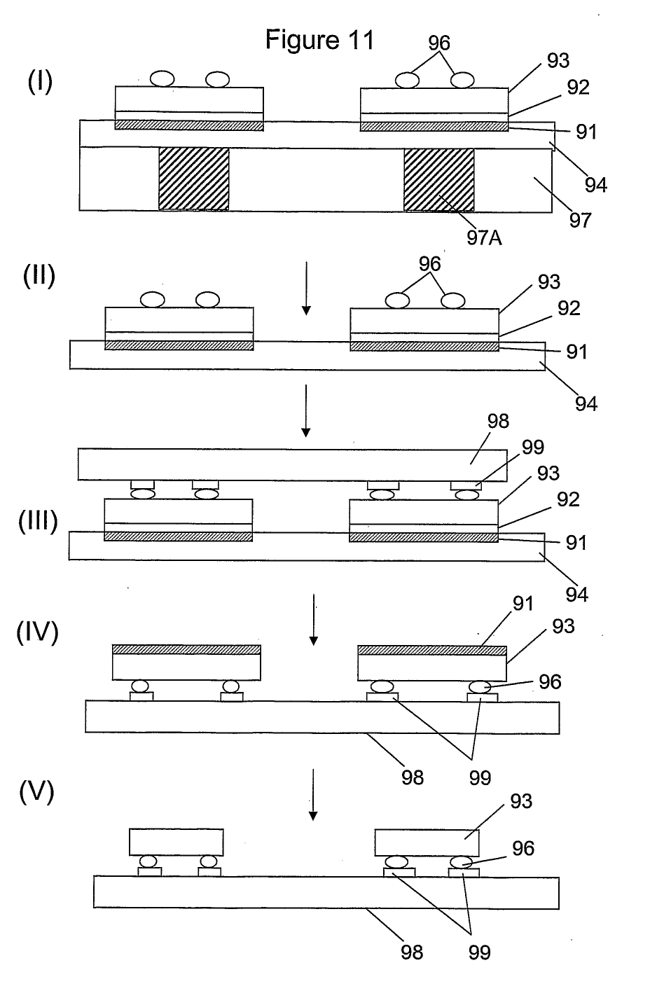

FIG. 11 shows an exemplary embodiment of a method of assembling semi-conductor chips having a ball grid array (BGA) onto a substrate;

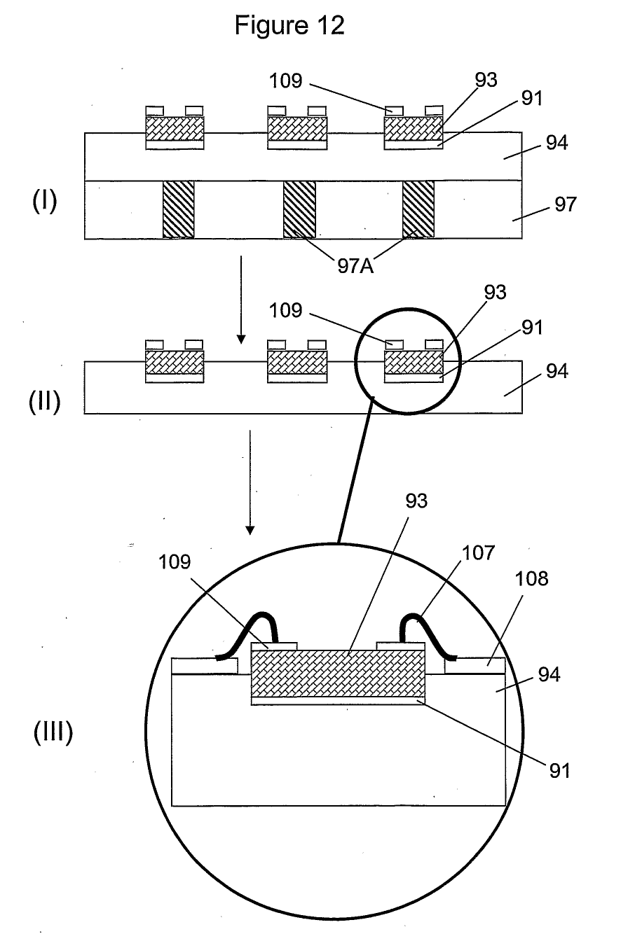

FIG. 12 shows an exemplary embodiment of a method of assembling semi-conductor chips onto a substrate using wire bonding;

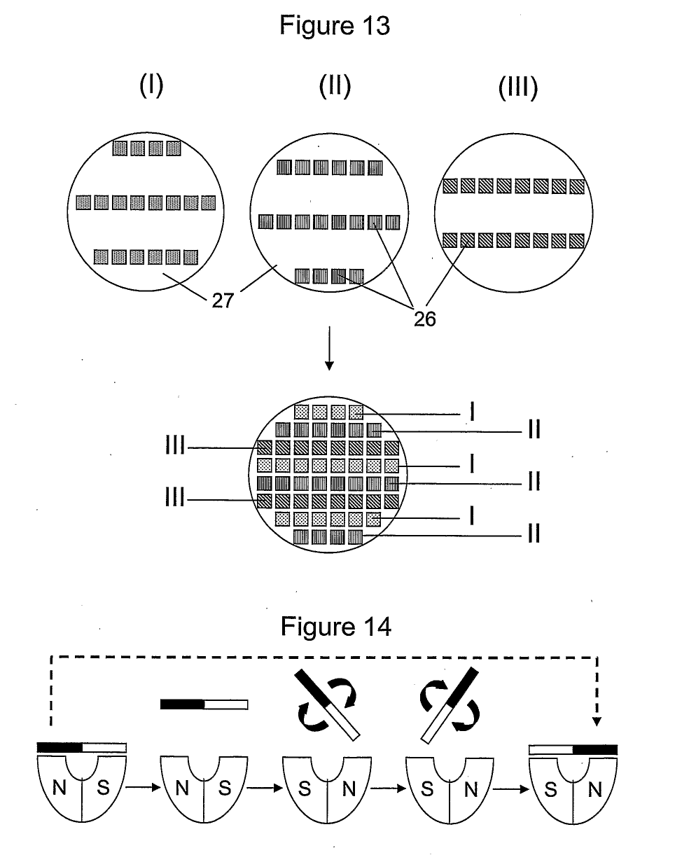

FIG. 13 shows an exemplary embodiment of a template wafer; and

FIG. 14 shows a model of a changing magnetic field and its effect on a chip having a magnetically coercive layer.

FIG. 1 shows a side view of an embodiment of assembly unit of the present invention. The assembly unit includes a template wafer 13 and a master wafer 14. The template wafer 13 has a recess 13a formed on its surface. This recess 13a is formed such that it is capable of accommodating therein a chip 12. In this embodiment, the chip 12 (which is illustrated to be a semi-conductor chip) has a mounting surface 12b, for mounting the chip onto a substrate, and an attachment surface 12a, which supports a magnetisable layer 11 formed on said attachment surface 12a.

As shown, the attachment surface 12a in this embodiment supports the magnetisable layer 11 directly. However, it should be noted that in an alternative embodiment, which will be discussed later, the magnetisable layer 11 may also be supported indirectly by said attachment surface 12b, i.e. through an intermediate layer or film. It should also be noted that the magnetisable layer of the chip 12 may also be referred to as a magnetisable film.

When the chip 12 is accommodated within the recess 13a, the attachment surface 12a, supporting said magnetisable layer 11 faces the bottom of recess 13a such that magnetisable layer 11 contacts or abuts at least a portion of the recess 13a as shown. Essentially, the orientation of the chip 12 is such that the attachment surface 12a is located deeper within the recess 13a while the mounting surface 12b is located nearer to the opening of the recess 13a, or facing said opening of the recess 13a.

In this embodiment, the master wafer 14 includes a magnetisable or magnetic element 16. The magnetic element 16 is shown to be embedded within the master wafer 14. In an alternative embodiment, the magnetic element 16 may be located on the surface of the master wafer 14. In yet another alternative embodiment, the magnetic element 16 may be removably inserted into the master wafer 14. In the embodiment of FIG. 1 the magnetic element 16 is essentially a soft magnetic material and thus, exhibits little or no magnetic properties on its own. Accordingly, it requires a magnetic source (or source magnet) 15 to align the domains of the magnetic element 16 such that it becomes magnetised and generates its own magnetic field. When the magnetic element 16 becomes magnetised by means of the magnetic source 15, and generates a corresponding magnetic field, it attracts the magnetic layer 11 supported on the attachment surface 12a of the chip 12 such that the chip 12 as a whole is manipulated till it is received into the recess 13a in the orientation as described above.

It should be noted that in alternative embodiments, the magnetic element 16 may be a permanent magnet and therefore, in such an alternative embodiment, it typically does not require any independent magnetic source to generate said magnetic field in order to attract the chip 12. Such alternative embodiments will be described in detail later on.

FIGS. 2A and 2B show alternative arrangements of the magnetic elements 15 and 15A with respect to the chip 12. The arrangement of FIGS. 2A and 2B is applicable in the both cases where the magnetic elements 15 and 15A are hard or soft magnetic materials. The magnetic elements are inserted, embedded or fixed horizontally in relation to the master wafer. In both the arrangements of FIGS. 2A and 2B, the south pole of each magnetic element is directly facing the north pole of an adjacent magnetic element thereby forming therebetween, a “magnetic cage”. During the assembly process the semiconductor chip 12 is “trapped” in this “magnetic cage”. This occurs with the chip 12 being either in between the magnetic elements 15 and 15A (as in FIG. 2A) or with one half of the magnetisable layer 11 resting over the one magnetic element 15, and the second half of the magnetisable layer 11 resting over the adjacent magnetic element 15A (as in FIG. 2B).

FIG. 3A shows a chip 22 and an embodiment of a magnetic element 23. The magnetic element 23 is a rectangular bar but it may also be a cylindrical rod. The chip 22, as previously described, supports a magnetisable layer 21 on a surface (attachment surface) thereof. Typically, when the magnetic element 23 generates a magnetic field, the orientation of the chip 12 having said magnetisable layer 21 supported thereon is such that the magnetisable layer 21 is nearer to the magnetic element 23.

FIG. 3B shows an embodiment of a master wafer 24. The master wafer 24 shown is a circular disc of a particular thickness. In this embodiment, the master wafer 24 has magnetic elements 23 that are cylindrical rods in a regular arrangement within it. As mentioned earlier, the magnetically coercive elements may be removably inserted into the master wafer 24 in addition to being embedded therein. The arrangement and location of the magnetic elements 23 within the master wafer 24 typically correspond to positions at which the chips 12 have to be positioned in, in order to be subsequently mounted onto a substrate (not shown) having corresponding chip mounting positions.

FIG. 3C shows an exploded view of an embodiment of an assembly unit according to the present invention. The assembly unit includes, apart from the above-mentioned master wafer 24, a template wafer 27. The template wafer 27 has a plurality of recesses 26 that are each capable of accommodating a chip 22, for example. The template wafer 27 is shown to be removably mounted onto the master wafer 24 such that each of the plurality of recesses 26 is proximate to at least one magnetic element 23 when the template wafer 27 is mounted onto the master wafer 24.

FIG. 4 shows a side view of another embodiment of the assembly unit. In this embodiment, the master wafer 24 has the wafer template 27 mounted thereon. The wafer template 27 has chips 26, having magnetisable layers 21, placed therein. The master wafer 24 includes recesses 800 for the magnetic elements 23 to be removably inserted into the master wafer 24.

FIG. 5A shows a chip 22 supporting a magnetisable layer 21 and another embodiment of a magnetic element 33. In this embodiment, the magnetic element 33 is U-shaped (or horseshoe shaped).

FIG. 5B shows another embodiment of a master wafer 24. This embodiment of the master wafer 24 includes the embodiment of the magnetic element 33 arranged or distributed regularly within the master wafer 24. Again, as mentioned previously, in alternative embodiments the magnetic element 33 may be removably inserted into the master wafer 24.

FIG. 5C shows an enlarged view of another embodiment of an assembly unit of the present invention. This embodiment of the assembly unit differs from that of FIG. 3C in that it includes magnetic elements 33. In the enlarged illustration, the U-shaped magnetic element 33 is shown to be embedded within the master wafer 24 with the template wafer 27 mounted thereon such that the recess of the template wafers 27 is almost coplanar, substantially adjacent (or proximate) or directly adjacent to the magnetic element 33.

The recess of template wafer 27 has therein a chip 22. The orientation of the chip 22 is such that its magnetisable layer 21 is within the recess and contacts the inner surfaces (or depths) of the recess while the mounting surface of the chip 22 typically faces or in some instances, depending on the chip, protrudes from the opening of the recess. In this embodiment, the chip 22 may be considered to be a semi-conductor chip. As such, said chip 22 includes bond pads 35 on its mounting surface. The spacing of the bond pads 35 on the chip 22 correspond to those found in the mounting position on a typical substrate, such as a printed circuit board (PCB), for example.

FIG. 6 shows a method of assembling chips according to an embodiment of the invention. In step I, the master wafer 24 having a plurality of magnetic elements (soft magnetic materials) 43 mounted thereon is shown. In this illustration, the embodiment of the magnetic element is in the form of a rectangular bar. Step II has the template wafer 27 mounted onto the master wafer 24 as previously described. In step III a plurality of chips 26, each supporting a magnetisable layer (not shown), are placed onto the template wafer 27.

In step IV, a magnetic source 44 is placed proximate to the master wafer 24 such that said magnetic source induces magnetism in the plurality of magnetic elements 43. As such, each of the plurality of magnetic elements 43 generates a magnetic field which in turn, magnetises the magnetisable layer supported by the chip 26. As shown in step IV, the magnetised chips 26 align and orientate themselves according to the polarisation of the magnetic field being generated by the master wafer 24 (by way of the magnetic elements 43). In step V, the magnetised chips 26 are further manipulated such that they are received into the recesses of the template wafer 27. This manipulation may be achieved by either modulating the magnetic field generated by an external solenoid or by supplementing the magnetic field with a mechanical agitation device, such as a vibration mechanism, for example, both of which are discussed later on. In the final step VI, the magnetic source 44 is removed and the magnetic elements 43, which retain their magnetism, hold the magnetised chips 26 in place within the recesses of the template wafer 27, in the orientation and alignment as previously described.

FIG. 7 shows another method of assembling semi conductor chips according to an exemplary embodiment of the invention. In this method, step I uses the embodiment of the master wafer 24 having the magnetic elements 33 as shown in FIG. 5B and as described above. Step II has the wafer template 27 placed onto the master wafer 24 to achieve the assembly unit shown in FIG. 5C. In step III, as above, a plurality of chips 26, each supporting a magnetically coercive layer, are placed onto the template wafer 27.

In this method, as compared to the method illustrated in FIG. 6, the embodiment of the assembly unit includes magnetic elements 33 that are permanent magnets, i.e. they are capable of generating a magnetic field on their own accord without the aid of an external magnetic source, unlike the embodiment of the assembly unit in FIG. 6.

Accordingly, in this embodiment, the chips 26, when placed onto the wafer template 27, undergo a re-orientation and arrangement due to the forces exerted by the magnetic field generated by the magnetic elements (permanent magnets) 33. In step IV, the chips 22 are, by way of the magnetic field and mechanical agitation if necessary, received into the recesses of the wafer template 27 in the orientation earlier specified. In step V, the wafer template 27, bearing the chips 26 within its recesses is removed from the master wafer 24 for mounting onto a substrate. Alternatively, the entire assembly unit (includes both the wafer template and master wafer) with the chips 26 may be aligned to allow for the chips 26 to be mounted onto said substrate.

FIG. 8 shows an enlarged view of the method of assembling a chip, where the chip is a semi-conductor chip, onto a substrate. Step I shows the magnetic element 33 embedded within the master wafer 24. The magnetic element 33, as mentioned earlier, is a permanent magnet and is magnetically polarised with its one half being a north pole and its other half being a south pole. Accordingly, the magnetic element generates a magnetic field in accordance with its magnetic polarity. Step II shows the template wafer 27 having a recess 61 being placed on the master wafer 24 such that the magnetic element 33 is proximate to the recess 61. Specifically, in this embodiment, the entire magnetic element 33 is located directly beneath the recess 61.

Steps III and IV show the placement of the semi-conductor chip 22 supporting its magnetic layer 21 and the subsequent manipulation by the magnetic field, respectively. In step III, the magnetic field polarises the magnetic layer 21 such that the polarity of the magnetic layer 21 is opposite to that of the magnetic element 33. Accordingly, the magnetic layer 21 is drawn or attracted towards the recess 61 of the template wafer 27, by the magnetic element 33, thereby also shifting the entire chip 22 that supports it.

In step IV, the chip 22 enters and is received by the recess 61. The orientation of the chip 22 is such that the magnetic layer 21, supported by the attachment surface of the chip, is at the bottom of the recess 61. Accordingly, the attachment surface supporting the magnetic layer 21 contacts or abuts at least a portion of the recess. The mounting surface of the chip 22, which opposes the attachment surface of the chip 22, faces the opening of the recess. In this embodiment, the mounting surface of the chip even protrudes slightly out of the recess 60 together with its bond pads 35 attached thereto.

Finally, in step V and VI, the master wafer 24 is removed from the template wafer 27 or vice versa, and a substrate 60, having corresponding bonding pads in a mounting position is aligned with the template wafer 27. The alignment between the template wafer 27 and the substrate 60 is such that the bond pads 63 of the substrate are aligned (typically in vertical alignment) with the bond pads 35 of the semi-conductor chip 22.

FIG. 9 shows a side view of an embodiment of the present invention. In this embodiment of the assembly unit, which includes the template wafer 72 and the master wafer 73 held together by a wafer carrier 74, the wafer carrier 74 also includes a solenoid 71 that circumferentially surrounds the periphery of the master wafer 73 and template wafer 72. The solenoid 71 is capable of modulating the original magnetic field (generated either directly or indirectly) of the magnetic elements (not shown) of the master wafer 73. In this embodiment of the assembly unit the magnetic elements are soft magnetic, and therefore, require an external magnetic source 75 in order to be magnetised and thus generate a suitable magnetic field. The magnetic source is mounted on a magnet carrier 76 such that it is translatable in a vertical and/or horizontal axis with respect to the master wafer. By mounting the magnetic source 75 on a movable magnet carrier 76, the strength of the magnetic field generated by the magnetic elements (not shown) (which in this embodiment are soft magnetic materials and thus have their magnetism induced by the magnetic source) may be varied accordingly and together with the solenoid 71, provide a greater degree of control so that individual chips (not shown) may be appropriately positioned and orientated as needed.

In this embodiment, the assembly unit also includes a vibration mechanism 77 for mechanically agitating the chips after they are placed on the template wafer 72. The vibration mechanism 77 may be necessary in order to provide sufficient mechanical motion to further facilitate the movement of the chips towards the recesses of the template wafer 72 together with the magnetic field. In some instances, the chip may be inverted, i.e. orientated such that the mounting surface is nearer to the magnetic element instead of the attachment surface supporting the magnetisable layer. In such cases, the mechanical agitation provided by the vibration mechanism 77 aids in flipping the chip around or at least facilitating the magnetic field in orientating the chip in the correct manner.

Typically, the vibration generator and the magnet carrier may be physically separated. In other words, the vibration generator may only vibrate the wafer carrier system 74 (which includes the wafer template 72, master wafer 73 and solenoid 71) and not the magnetic source (magnet) 75.

FIG. 10A and FIG. 10B show a top view and a side view of an embodiment of the present invention having a plurality of solenoids surrounding the template wafer 27 and master wafer 24. In FIG. 10A, the template wafer 27 has a plurality of chips 26 thereon. From the top view, the template wafer 27 has a pair of solenoids 81 on either side thereof, which aid in modulating the strength of the magnetic field across the diametric length of the template wafer 27.

In FIG. 10B, the side view of the embodiment, a third solenoid 81 is shown to be beneath the master wafer 24. This third solenoid 81 serves to modulate the vertical strength of the magnetic field across the template wafer 27, as generated by the master wafer 24.

FIG. 11 shows an exemplary method of assembling semi-conductor chips onto a substrate. The method comprises the following steps (I)-(V) below:

However, prior to the processing steps shown in (I)-(V), an initial processing step that is not illustrated is one where a layer of polymer film is deposited on an undiced wafer of semi-conductor chips. One side of the polymer film adheres to an attachment surface of each undiced semi-conductor chip while the other side of the layer of polymer film supports a magnetisable layer (or film). The magnetisable layer is formed such that the attachment surface of the semi-conductor chip supports the magnetisable layer, via the other side of the polymer film. As mentioned earlier, the magnetisable layer may also include a protective layer thereon.

In this embodiment, the semi-conductor chip also includes a suitable number of solder bumps (flip chip design) attached to a mounting surface [via underbump metallization (UBM), for example] for subsequent mounting onto a suitable substrate, such as a printed circuit board (PCB), for example. Prior to assembly on the substrates, the semi-conductor chips supporting the magnetisable layer may be diced by any suitable method. An example of a suitable method may be the use of laser scribing to form scribe lines between each semi-conductor chip followed by an application of a mechanical force, such as rolling, to break the wafer along said scribe lines. Once the chips are diced, they may be placed in a chip circulation system where they are transported and deposited onto an assembly unit such as one shown in FIGS. 5-10. The assembly unit orientates the chips into the recesses of the template wafer to arrive at the stage shown in (I).

(I): Template wafer 94 holds the semi-conductor chip 93 in the orientation as shown with the attachment surface of the chip 93 (supporting the magnetisable layer 91) received into the innermost portion of the recess of the template wafer 94. Accordingly, the mounting surface having the solder bumps 96 thereon is facing outwards (and protruding) from the opening of the recess.

(II): In this step, the template wafer 94 is removed from the master wafer 97. The master wafer 97 includes magnetic elements 97A.

(III): In this step, the template wafer 94 aligns with the substrate 98, such as a PCB, as mentioned earlier, and arranges the semi-conductor chip 93 such that the solder bumps 96 contact bonding pads 99 of the substrate 98.

(IV): The assembly unit then releases the assembled semi-conductor chips from the template wafer 94 by reducing or switching off the magnetic field generated by the master wafer (not shown).

(V): In this final step, the chip 93 is electrically connected to the substrate, via its bonding pads 99, by soldering, which may be in a belt furnace or by hot gas, for example. Typically, prior to attaching the chip 93 to the substrate 98, the polymer layer 92 is removed, and therefore so is the magnetisable layer 91 attached thereto. In this regard, the polymer layer 92 may be removed by mechanical, chemical or heating means, for example.

In FIG. 11, though the magnetisable layer is shown to be removed, it may not always be necessary to do so. If the magnetisable layer is formed of a soft magnetic material and thus, has a propensity to lose its magnetism once removed from any governing magnetic field, then provided that the magnetisable layer does not interfere in the functionality of the chip, it may be left on said chip.

FIG. 12 shows another exemplary method of assembling semi-conductor chips onto a substrate. The pre-processing step as described earlier in relation to FIG. 11 is also applicable here with the exception that no solder bumps are present on the semi-conductor chips. Instead, this embodiment of the method uses semi-conductor chips suited for wire bonding.

In this exemplary method, the steps (I) and (II) are similar to that as illustrated in the method of FIG. 11 with the exception being that the semi-conductor chip 93 relies on wire bonding to be attached or mounted onto the bond pad or the substrate 108. In step (III), the bond pad or substrate 108 (or conversely the template wafer 94) is arranged such that the semi-conductor chip 93 is in a mounting position with respect to the bond pad or substrate 108. The bond pad or substrate 108 has an opening through which a portion of the semi-conductor chip 93 extends. Following the alignment of the semi-conductor chip 93 to the bond pad or substrate 108, the process of wire bonding attaches fine copper or gold wires 107 from the bonding pads 109 located on the chip 93 to the bonding pads or the substrate 108.

FIG. 13 shows an embodiment of a template wafer 27 having thereon three pluralities of different semi-conductor chips 26. The three pluralities of chips on the template wafer 27 is the combination of using master wafers I, II and III. I, II, and III refer to three different master wafers, which would result in three different types of chips being assembled on the same substrate. In this case the template wafer 27 may be just patterned with one regular pattern since the final arrangement of chips on the template wafer 27 is defined by the master wafers. Using this method of assembly permits more than one type of chip to be mounted onto a substrate in a consecutive manner.

FIG. 14 shows an exemplary effect of a magnetic field on a magnetisable layer. A magnetic element generates a field that typically runs from the North Pole to the South Pole and as such, induces an opposite polarity in the magnetisable layer thus attracting it as shown. However, when the polarity of the magnetic element is suddenly reversed (assuming that the magnetic element is an electromagnet, for example), the direction of the field is also reversed and as such, the magnetisable layer re-orientates itself and continues to be attracted to the magnetic element. This method may be used to re-orientate chips that are not of the correct orientation during the assembling process. In addition, if individual magnetic elements are controllable, then at a very basic level, each individual chip in the assembly process can be manipulated as needed with regard to orientation and arrangement.

It is to be noted that the above description of various exemplary embodiments of the invention only serves to aid in the better understanding of the invention. As such, the present invention is not be construed as being limited to the illustrated embodiments and its corresponding description, but, only as defined in the appended claims that follow.

1. A magnetically-assisted chip assembly unit for at least one chip, said chip having a mounting surface and an attachment surface, wherein the attachment surface supports a magnetisable layer thereon and opposes said mounting surface, onto a substrate that has a corresponding chip mounting surface, said unit comprising:
a template wafer having at least one recess adapted to accommodate therein said chip; and
a master wafer having at least one magnetisable and/or magnetic element;
wherein the template wafer is mounted on the master wafer and said magnetisable or magnetic element of the master wafer is located at least proximate to the at least one recess of the template wafer such that a magnetic field generated by the magnetisable or magnetic element is capable of manipulating the chip into the recess wherein the attachment surface of the chip faces at least a portion of the recess, and the mounting surface of the chip faces the opening of the recess.

2. The assembly unit according to claim 1, wherein the magnetic element is a permanent magnet.

3. The assembly unit according to claim 1, wherein the magnetisable element is made from a soft magnetic material.

4. The assembly unit according to claim 3, further comprising a source magnet proximate to the magnetisable element, said source magnet being adapted to be capable of inducing a state of magnetism in the magnetisable element such the magnetisable element generates a magnetic field sufficient to manipulate the chip.

5. The assembly unit according to claim 4, wherein the source magnet is a permanent magnet or an electromagnet.

6. The assembly unit according to claim 4, further comprising a source magnet carrier, wherein the source magnet is mounted thereon such that it is translatable in a vertical and/or horizontal axis with respect to the master wafer.

7. The assembly unit according to claim 1, wherein the master wafer and/or template wafer is rotatable about its diametric axis.

8. The assembly unit according to claim 1, wherein the magnetisable or magnetic element is a circular rod, a rectangular bar or is U-shaped.

9. The assembly unit according to claim 1, wherein the magnetisable or magnetic element has its one end magnetically polarised as a north pole and its other end magnetically polarised as a south pole.

10. The assembly unit according to claim 1, wherein the template wafer and master wafer comprise a plurality of recesses and a corresponding plurality of magnetisable or magnetic elements respectively, where each of the plurality of recesses is located on the template wafer to correspond to a respective chip mounting position on the substrate, and each of the plurality of magnetisable or magnetic elements is located at least proximate to at least one recess such that a magnetic field generated by the magnetisable or magnetic element is capable of manipulating the chip.

11. The assembly unit according to claim 1, wherein the magnetisable or magnetic element is within the master wafer.

12. The assembly unit according to claim 1, wherein the magnetisable or magnetic element is arranged on a surface of the master wafer.

13. The assembly unit according to claim 1, wherein the template wafer is removably mounted onto the master wafer.

14. The assembly unit according to claim 1, further comprising at least one solenoid, wherein said at least one solenoid is arranged at least proximate to the periphery of the master wafer, such that the at least one solenoid is capable of modulating the magnetic field generated by the magnetisable or magnetic element, thereby further manipulating the chip.

15. The assembly unit according to claim 1, wherein the magnetisable or magnetic element is made from a material selected from the group consisting of iron (Fe), cobalt (Co), nickel (Ni), composites of powdered iron oxide and barium/strontium carbonate ceramic, alloys of aluminium, nickel and cobalt with iron (alnico), samarium cobalt, neodymium iron boron (NdFeB), Permalloy (Ni₈₁Fe₁₉), Ni_{1-X}ZnₓFeO₃, CoPtCr or any combination thereof.

16. The assembly unit according to claim 1, further comprising a vibration mechanism adapted such that the vibrations produced by said vibration mechanism facilitate the entry of the chip into the recess of the template wafer.

17. The assembly unit according to claim 1, wherein the magnetisable layer of the chip abuts at least a portion of the recess.

18. The assembly unit according to claim 1, wherein the magnetisable layer of the chip includes a protective layer disposed thereon.

19. A method of assembling at least one chip having a mounting surface and an attachment surface that opposes said mounting surface, onto a substrate that has a corresponding chip mounting surface, said method comprising:
forming a magnetisable layer adjacent on the attachment surface;
placing the chip having the magnetisable layer on a template wafer, said template wafer having at least one recess adapted to accommodate therein said chip;
generating a suitable magnetic field by means of a magnetic field generation device such that said magnetic field is capable of manipulating the chip into the recess, via its magnetisable layer, such that the magnetisable layer of the chip abuts at least a portion of the recess and the mounting surface of the chip faces an opening of the recess; and
aligning, via the generated magnetic field, the template wafer with respect to the substrate such that the mounting surface of the chip contained in the recess contacts the mounting surface of the substrate.

20. The method of claim 19, further comprising:
forming a polymer film on the attachment surface between the magnetisable layer and the attachment surface; and
removing the polymer film and the magnetisable layer deposited thereon from the attachment surface.

21.-22. (canceled)

23. A magnetic field generation device for use in a magnetically-assisted chip assembly unit for assembling at least one chip having a mounting surface and an attachment surface, wherein the attachment surface has a magnetisable layer supported thereon and opposes said mounting surface, onto a substrate that has a corresponding chip mounting surface, said device comprising:
a master wafer having at least one magnetisable or magnetic element;
wherein the template wafer is mounted on the master wafer and said magnetisable or magnetic element is located at least proximate to the at least one recess such that a magnetic field generated by the magnetisable or magnetic element is capable of manipulating the chip.

24.-25. (canceled)

26. The device according to claim 23, wherein the master wafer comprises at least one magnetisable element and at least one magnetic element.

27. The device according to claim 26, further comprising
a source magnet proximate to the magnetisable element, wherein said source magnet is adapted to be capable of inducing a state of magnetism in the magnetisable element such the magnetisable element generates a magnetic field sufficient to manipulate the chip, wherein the source magnet is a permanent magnet or an electromagnet; and
a source magnetic carrier, wherein the source magnet is mounted thereon such that it is translatable in a vertical and/or horizontal axis with respect to the master wafer.

28.-29. (canceled)

30. The device according to claim 23, wherein the master wafer is rotatable about its diametric axis;
wherein the magnetisable or magnetic element is a circular rod, a rectangular bar or is U-shaped;
wherein the magnetisable or magnetic element has its one end magnetically polarised as a north pole and its other end magnetically polarised as a south pole; and
wherein the magnetisable or magnetic element is within the master wafer, or is arranged on a surface of the master wafer.

31.-34. (canceled)

35. The device according claim 23, wherein the master wafer includes a mounting mechanism for mounting a template wafer, wherein said template wafer has at least one recess adapted to accommodate therein said chip, such that said magnetisable or magnetic element is located at least proximate to the at least one recess such that a magnetic field generated by the magnetisable or magnetic element is capable of manipulating the into the recess, such that the magnetisable layer of the chip abuts at least a portion of the recess and the mounting surface of the chip faces the opening of the recess.

36.-38. (canceled)

39. A system assembling at least one chip having a mounting surface and an attachment surface, wherein the attachment surface has a magnetisable layer supported thereon and opposes said mounting surface, onto a substrate that has a corresponding chip mounting surface, said system comprising:
a magnetically-assisted chip assembly unit, as defined in claim 1; and
a bonding mechanism to electrically and physically connect the chip to the substrate.

40. (canceled)

41. A system according to claim 39, further comprising a magnetisable layer removal means.

42. A system according to claim 41, wherein the magnetisable layer removal means includes mechanical means, chemical means, heating means or any combination thereof.
